(19) United States
(12) Patent Application Publication
(10) Pub. No.: US 2025/0271748 A1
(43) Pub. Date: Aug. 28, 2025

(54) PHASE-SHIFTING PHOTOMASK

(71) Applicant: Powerchip Semiconductor Manufacturing Corporation, Hsinchu (TW)

(72) Inventor: Yi-Kai Lai, Taoyuan City (TW)

(73) Assignee: Powerchip Semiconductor Manufacturing Corporation, Hsinchu (TW)

(21) Appl. No.: 18/631,060

(22) Filed: Apr. 10, 2024

(30) Foreign Application Priority Data
Feb. 23, 2024 (TW) 113106537

(51) Int. Cl. G03F 1/26

(52) U.S. Cl. CPC G03F 1/26

(57) ABSTRACT

The present disclosure provides a phase-shifting photomask including a transparent substrate, a main feature pattern disposed on the transparent substrate and including a plurality of first phase-shifting patterns, and a bridging feature pattern disposed on the transparent substrate and including a plurality of second phase-shifting patterns between the two neighboring first phase-shifting patterns. The plurality of first phase-shifting patterns extend in a first direction and are spaced apart from each other in a second direction crossing the first direction. The plurality of second phase-shifting patterns extend in the second direction and are spaced apart from each other in the first direction.

### CROSS-REFERENCE TO RELATED APPLICATION

This application claims the priority benefit of Taiwan application serial no. 113106537,filed on Feb. 23, 2024. The entirety of the above-mentioned patent application is hereby incorporated by reference herein and made a part of this specification.

### BACKGROUND

### Technical Field

The present invention relates to a mask for a semiconductor process, and more particular to a phase-shifting photomask.

### Description of Related Art

As the sizes of electronic devices continue to shrink and the user's requirements for the performance of the electronic devices continue to increase, a person having ordinary skill in the art is striving for making the electronic devices include more components while maintaining the existing horizontal area, or maintaining the number of the existing components while having a minimized horizontal area. However, either of the situations needs to reduce the feature sizes of the devices or the line widths of the interconnections.

In the current processes, an extreme ultraviolet (EUV) with a small exposure wavelength is usually used as the light source of the exposure machine, as such the interconnections with fine line widths or the devices with compact feature sizes can be realized by narrowing the wavelength of the exposure light source. However, the lithography process that uses the EUV as the light source is expensive and energy-consuming, and in the case where the sizes of the electronic devices continue to shrink, the lithography process uses the EUV as the light source will still be unable to satisfy the desired size at that time. Accordingly, a person having ordinary skill in the art continues to find the ways other than narrowing the wavelength of the exposure light source.

### SUMMARY

The invention provides a phase-shifting photomask in which first phase-shifting patterns are designed to be extending in a first direction and spaced apart from each other in a second direction crossing the first direction, and the second phase-shifting patterns are designed to be disposed between two neighboring first phase-shifting patterns, extending in the second direction, and spaced apart from each other in the first direction. As such, the resolution of the phase-shifting photomask can be improved by the second phase-shifting patterns bridging between the first phase-shifting patterns included in a main feature pattern, so that the devices with compact feature sizes or the interconnections with fine line widths can be realized.

An embodiment of the present invention provides a phase-shifting photomask including a transparent substrate, a main feature pattern and a bridging feature pattern. The main feature pattern is disposed on the transparent substrate and includes a plurality of first phase-shifting patterns, wherein the plurality of first phase-shifting patterns extend in a first direction and are spaced apart from each other in a second direction crossing the first direction. The bridging feature pattern is disposed on the transparent substrate and includes a plurality of second phase-shifting patterns between two neighboring first phase-shifting patterns, wherein the plurality of second phase-shifting patterns extend in the second direction and are spaced apart from each other in the first direction.

In some embodiments, each of the main feature pattern and the bridging feature pattern comprises a material having a light transmittance greater than about 97%.

In some embodiments, the main feature pattern comprises a material capable of allowing a phase of a light beam passing therethrough shifting about 177° to about 183°.

In some embodiments, the bridging feature pattern comprises a material capable of allowing a phase of a light beam passing therethrough shifting about 177° to about 183°.

In some embodiments, the main feature pattern and the bridge feature pattern have the same light transmittance, and the light beams passed through the main feature pattern and the bridge feature pattern have the same phase angle.

In some embodiments, the light beams passed through the main feature pattern and the bridging feature pattern include a dipole illumination, and an optical axis of the dipole illumination is parallel to the second direction.

In some embodiments, two opposite ends of each second phase-shifting pattern in the second direction are directly in contact with the two neighboring first phase-shifting patterns respectively.

In some embodiments, a length of each second phase-shifting pattern extending in the second direction is greater than a width of each first phase-shifting pattern in the second direction.

In some embodiments, a width of each second phase-shifting pattern in the first direction is smaller than the width of each first phase-shifting pattern.

In some embodiments, the first direction is orthogonal to the second direction.

Based on the above, in the aforementioned phase-shifting photomask, the first phase-shifting patterns extend in the first direction and are spaced apart from each other in the second direction crossing the first direction, and the second phase-shifting patterns are disposed between two neighboring first phase-shifting patterns, extending in the second direction, and spaced apart from each other in the first direction. As such, the resolution of the phase-shifting photomask can be improved by the second phase-shifting patterns of the bridging feature pattern bridging between the first phase-shifting patterns of the main feature pattern, so that the devices with compact feature sizes or the interconnections with fine line widths can be realized.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a phase-shifting photomask according to an embodiment of the present invention.

FIG. 2 is a schematic cross-section view taken along a line A-A′ in FIG. 1.

FIG. 3 is a schematic view showing a light beam passing through a phase-shifting photomask according to an embodiment of the present invention.

FIG. 4 is a schematic view showing a pattern imaged by a light beam passed through a phase-shifting photomask according to an embodiment of the present invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

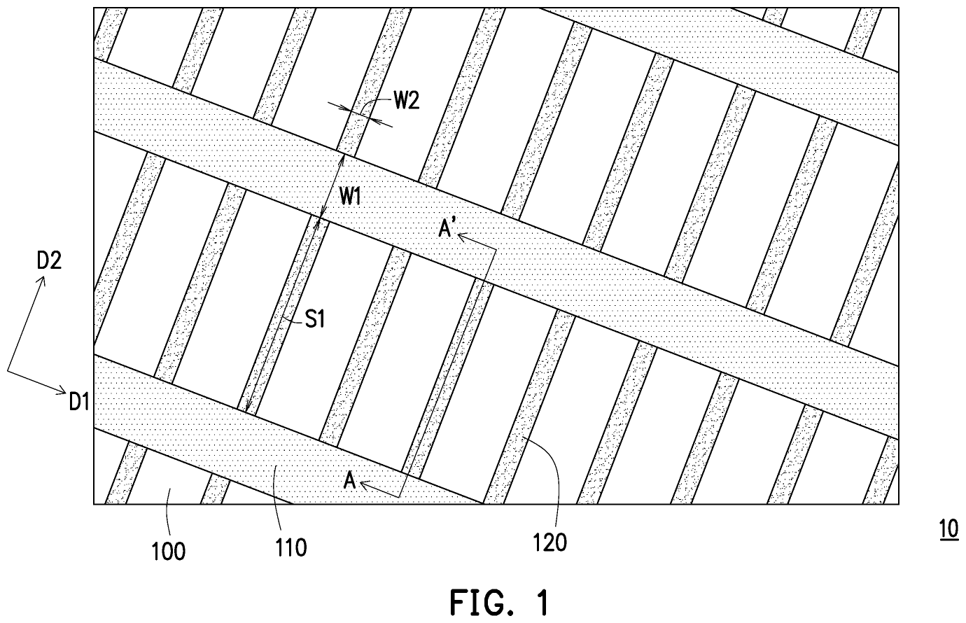

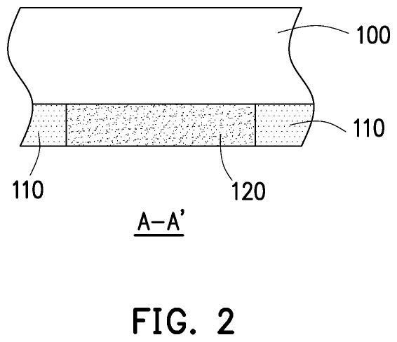

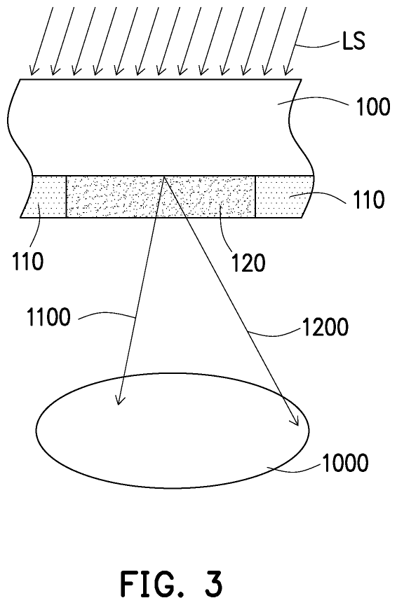

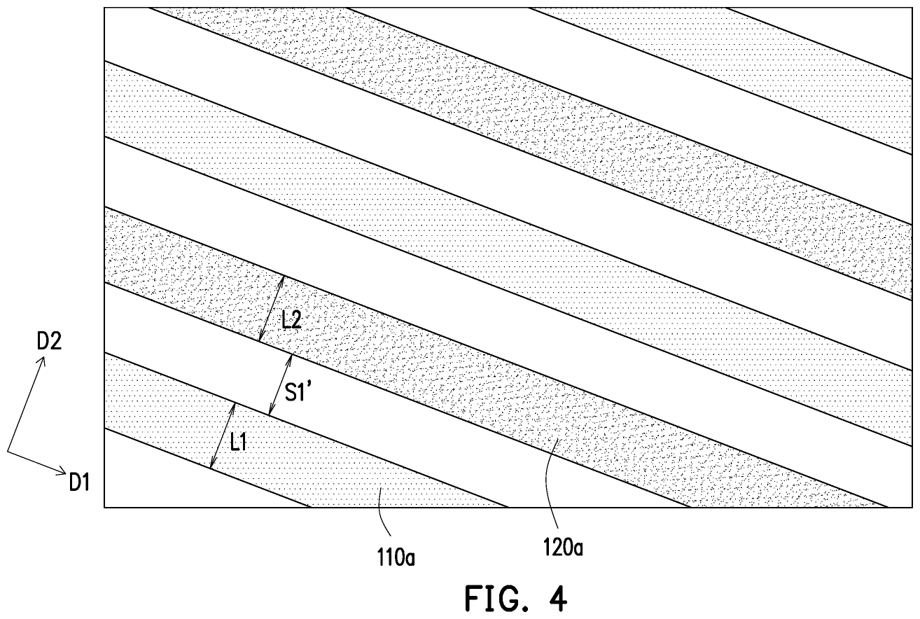

FIG. 1 is a schematic top view of a phase-shifting photomask according to an embodiment of the present invention. FIG. 2 is a schematic cross-section view taken along a line A-A′in FIG. 1. FIG. 3 is a schematic view showing a light beam passing through a phase-shifting photomask according to an embodiment of the present invention. FIG. 4 is a schematic view showing a pattern imaged by a light beam passed through a phase-shifting photomask according to an embodiment of the present invention.

Referring to FIG. 1 and FIG. 2, a phase-shifting photomask 10 includes a transparent substrate 100, a main feature pattern and a bridging feature pattern. The main feature pattern is disposed on the transparent substrate 100 and includes a plurality of first phase-shifting patterns 110. The bridging feature pattern is disposed on the transparent substrate 100 and includes a plurality of second phase-shifting patterns 120 between two neighboring first phase-shifting patterns 110. The first phase-shifting patterns 110 extend in a first direction D1 and are spaced apart from each other in a second direction D2 crossing the first direction D1, and the second phase-shifting patterns 120 extend in the second direction D2 and are spaced apart from each other in the first direction D1. As such, the resolution of the phase-shifting photomask 10 can be improved by the second phase-shifting patterns 120 of the bridging feature pattern bridging between the first phase-shifting patterns 110 of the main feature pattern, so that the devices with compact feature sizes or the interconnections with fine line widths can be realized. In some embodiments, the first direction D1 is orthogonal to the second direction D2.

Referring to FIG. 3 and FIG. 4, when a light beam LS passes through the second phase-shifting pattern 120 (i.e., the bridging feature pattern) bridging between the first phase-shifting patterns 110 (i.e., the main feature pattern), a zero-order diffracted light 1100 and a first-order diffracted light 1200 are both irradiated to a desired area 1000, so that the zero-order diffracted light 1100 and the first-order diffracted light 1200 are capable of performing an interferometric optical imaging within the desired area 1000, and thus the resolution of the phase-shifting photomask 10 can be increased.

In some embodiments, in the case where a width W1 of the first phase-shifting pattern 110 in the second direction D2 is about 36 nm and the first phase-shifting patterns 110 are spaced apart from each other by a distance S1 of about 108 nm in the second direction D2 (i.e., a length of the second phase-shifting pattern 120 extending in the second direction D2), a pattern imaged by a light beam passed through the phase-shifting photomask 10 is shown in FIG. 4. The pattern incudes first patterns 110a derived from the first phase-shifting patterns 110 and second patterns 120a derived from the second phase-shifting patterns 120. The sizes L1 of the first patterns 110a in the second direction D2 are approximately equal to the width W1 (i.e., 36 nm) of the first phase-shifting pattern 110 in the second direction D2, the sizes L2 of the second patterns 120a in the second direction D2 are about 36 nm, and distances S1′ between the first patterns 110a and the second patterns 120a in the second direction D2 are about 36 nm. From the above embodiment, the pitch of the first phase-shifting pattern 110 is about 144 nm, and the pitch of the patterns imaged by the light beam passed through the phase-shifting photomask 10 is about 72 nm. That is to say, the second phase-shifting patterns 120 bridging between the first phase-shifting patterns 110 can improve the resolution of phase-shifting photomask 10 significantly.

The transparent substrate 100 may include a material having a light transmittance of 100%. The transparent substrate 100 may include a material in which the phase of the light beam passing therethrough does not shift. In some embodiments, the transparent substrate 100 may include transparent materials such as quartz.

Each of the main feature pattern including the first phase-shifting patterns 110 and the bridging feature pattern including the second phase-shifting patterns 120 includes a material having a light transmittance greater than about 97%. In some embodiments, each of the first phase-shifting patterns 110 and second phase-shifting patterns 120 includes a material having a light transmittance of about 98%, 99%, or 100%.

The main feature pattern including the first phase-shifting patterns 110 includes a material capable of allowing the phase of the light beam (e.g., the light beam LS shown in FIG. 3) passing therethrough shifting about 177° to about 183°. In some embodiments, the first phase-shifting patterns 110 include materials capable of allowing the phase of the light beam (e.g., the light beam LS shown in FIG. 3) passing therethrough shifting about 180°.

The bridging feature pattern including the second phase-shifting patterns 120 includes a material capable of allowing the phase of the light beam (e.g., the light beam LS shown in FIG. 3) passing therethrough shifting about 177° to about 183°. In some embodiments, the second phase-shifting patterns 120 include materials capable of allowing the phase of the light beam (e.g., the light beam LS shown in FIG. 3) passing therethrough shifting about 180°.

In some embodiments, the first phase-shifting patterns 110 and the second phase-shifting patterns 120 may each include a material such as a hybrid organic siloxane polymer (HOSP), a methyl silsesquioxane (MSQ), or a hydrogen silsesquioxane (HSQ).

In some embodiments, the main feature pattern including the first phase-shifting patterns 110 and the bridging feature pattern including the second phase-shifting patterns 120 may have the same light transmittance, and the light beams (e.g., the light beams LS shown in FIG. 3) passed through the main feature pattern including the first phase-shifting patterns 110 and the bridging feature pattern including the second phase-shifting patterns 120 have the same phase angle. In some embodiments, the phase angle of the light beam passed through the first phase-shifting patterns 110 or the second phase-shifting patterns 120 can be estimated by the following formula: P=2π(n−1)T/λ, where P is the phase angle; n is the refractive index of the first phase-shifting pattern 110 or the second phase-shifting pattern 120; T is the thickness of the first phase-shifting pattern 110 or the second phase-shifting pattern 120; and λ is the wavelength of the light beam LS. In some embodiments, the wavelength of the light beam LS is 193 nm (e.g. an exposure light source using ArF).

In some embodiments, the light beams (e.g., the light beams LS shown in FIG. 3) passed through the main feature pattern including the first phase-shifting patterns 110 and the bridging feature pattern including the second phase-shifting patterns 120 include a dipole illumination in which an optical axis of the dipole illumination is parallel to the second direction D2. That is, the second phase-shifting patterns 120 is designed to be extending in a direction (i.e., second direction D2) parallel to the optical axis of the dipole illumination.

In some embodiments, as shown in FIG. 1, two opposite ends of each second phase-shifting pattern 120 in the second direction D2 may be directly in contact with the two neighboring first phase-shifting patterns 110 respectively. In some embodiments, a length of each second phase-shifting pattern 120 extending in the second direction D2 (i.e., the distance S1 between the first phase-shifting patterns 110 in the second direction D2) is greater than a width W1 of each first phase-shifting pattern 110 in the second direction D2. In some embodiments, the width W2 of each second phase-shifting pattern 120 in the first direction D1 is smaller than the width W1 of each first phase-shifting pattern 110 in the second direction D2. In some embodiments, the width W2 of the second phase-shifting pattern 120 in the first direction D1 may be about 10 nm. In some embodiments, the pitch of the second phase-shifting pattern 120 in the first direction D1 may be about 46 nm.

In summary, in the above phase-shifting photomask, the first phase-shifting patterns extend in the first direction and are spaced apart from each other in the second direction crossing the first direction, and the second phase-shifting patterns are disposed between two neighboring first phase-shifting patterns, extending in the second direction, and spaced apart from each other in the first direction. As such, the resolution of the phase-shifting photomask can be improved by the second phase-shifting patterns of the bridging feature pattern bridging between the first phase-shifting patterns of the main feature pattern, so that the devices with compact feature sizes or the interconnections with fine line widths can be realized.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A phase-shifting photomask, comprising:
a transparent substrate;
a main feature pattern disposed on the transparent substrate and comprising a plurality of first phase-shifting patterns, wherein the plurality of first phase-shifting patterns extend in a first direction and are spaced apart from each other in a second direction crossing the first direction; and
a bridging feature pattern disposed on the transparent substrate and comprising a plurality of second phase-shifting patterns between two neighboring first phase-shifting patterns, wherein the plurality of second phase-shifting patterns extend in the second direction and are spaced apart from each other in the first direction.

2. The phase-shifting photomask of claim 1, wherein each of the main feature pattern and the bridging feature pattern comprises a material having a light transmittance greater than about 97%.

3. The phase-shifting photomask of claim 2, wherein the main feature pattern comprises a material capable of allowing a phase of a light beam passing therethrough shifting about 177° to about 183°.

4. The phase-shifting photomask of claim 3, wherein the bridging feature pattern comprises a material capable of allowing a phase of a light beam passing therethrough shifting about 177° to about 183°.

5. The phase-shifting photomask of claim 4, wherein the main feature pattern and the bridge feature pattern have the same light transmittance, and the light beams passed through the main feature pattern and the bridge feature pattern have the same phase angle.

6. The phase-shifting photomask of claim 4, wherein the light beams passed through the main feature pattern and the bridging feature pattern comprise a dipole illumination, and an optical axis of the dipole illumination is parallel to the second direction.

7. The phase-shifting photomask of claim 1, wherein two opposite ends of each second phase-shifting pattern in the second direction are directly in contact with the two neighboring first phase-shifting patterns respectively.

8. The phase-shifting photomask of claim 1, wherein a length of each second phase-shifting pattern extending in the second direction is greater than a width of each first phase-shifting pattern in the second direction. 5

9. The phase-shifting photomask of claim 8, wherein a width of each second phase-shifting pattern in the first direction is smaller than the width of each first phase-shifting pattern.

10. The phase-shifting photomask of claim 1, wherein the first direction is orthogonal to the 10 second direction.
